(19) United States
(12) Patent Application Publication
(10) Pub. No.: US 2007/0096250 A1
(43) Pub. Date: May 3, 2007

(54) Semiconductor device and method of manufacturing the same

(75) Inventors: Kunio Watanabe, Sakata (JP); Tomo Takaso, Chino (JP); Masahiro Hayashi, Sakata (JP); Takahisa Akiba, Tsuruoka (JP); Susumu Kenmochi, Tsuruoka (JP)

Correspondence Address: HARNESS, DICKEY & PIERCE, P.L.C., P.O. BOX 828, BLOOMFIELD HILLS, MI, 48303, US

(73) Assignee: Seiko Epson Corporation

(21) Appl. No.: 11/529,635

(22) Filed: Sep. 28, 2006

(30) Foreign Application Priority Data
Oct. 27, 2005 (JP) 2005-312924

(51) Int. Cl. H01L 29/40; H01L 21/44

(52) U.S. Cl. 257/529; 438/601; 438/622; 257/758

(57) ABSTRACT

A semiconductor device including: a semiconductor layer; a transistor formed in the semiconductor layer; a first interlayer dielectric formed above the semiconductor layer; a plurality of first interconnect layers formed above the first interlayer dielectric; a second interlayer dielectric formed over the first interlayer dielectric and the first interconnect layers; a plurality of second interconnect layers and an electrode pad which are formed above the second interlayer dielectric, the second interconnect layers being uppermost interconnects; a passivation layer formed over the second interlayer dielectric, the second interconnect layers, and the electrode pad; and an opening formed in the passivation layer to expose at least part of the electrode pad, a minimum distance between the second interconnect layers being greater than a minimum distance between the first interconnect layers.

Japanese Patent Application No. 2005-312924, filed on Oct. 27, 2005, is hereby incorporated by reference in its entirety.

### BACKGROUND OF THE INVENTION

The present invention relates to a semiconductor device and a method of manufacturing the same.

In a semiconductor device mounted by wireless bonding, a bump is formed on an electrode pad, for example. In a semiconductor device disclosed in JP-A-2000-357701, an electrode pad is covered with a passivation layer, and a part of a bump is embedded in an opening formed in the passivation layer. If a part of the bump is embedded in the opening in the passivation layer, a concave section may be formed in the surface of the bump at a position over the opening due to the depth of the opening.

### SUMMARY

According to a first aspect of the invention, there is provided a semiconductor device comprising:

a semiconductor layer;

a transistor formed in the semiconductor layer;

a first interlayer dielectric formed above the semiconductor layer;

a plurality of first interconnect layers formed above the first interlayer dielectric;

a second interlayer dielectric formed over the first interlayer dielectric and the first interconnect layers;

a plurality of second interconnect layers and an electrode pad which are formed above the second interlayer dielectric, the second interconnect layers being uppermost interconnects;

a passivation layer formed over the second interlayer dielectric, the second interconnect layers, and the electrode pad; and

an opening formed in the passivation layer to expose at least part of the electrode pad,

a minimum distance between the second interconnect layers being greater than a minimum distance between the first interconnect layers.

According to a second aspect of the invention, there is provided a method of manufacturing a semiconductor device, the method comprising:

forming a transistor in a semiconductor layer;

forming a first interlayer dielectric above the semiconductor layer;

forming a plurality of first interconnect layers and a fuse above the first interlayer dielectric;

forming a second interlayer dielectric over the first interlayer dielectric, the first interconnect layers, and the fuse;

forming a plurality of second interconnect layers and an electrode pad above the second interlayer dielectric;

forming a passivation layer over the second interlayer dielectric, the second interconnect layers, and the electrode pad;

forming an opening in the passivation layer to expose at least part of the electrode pad; and

forming another opening in the second interlayer dielectric and the passivation layer above the fuse in such a manner that the fuse is not exposed,

a minimum distance between the second interconnect layers being greater than a minimum distance between the first interconnect layers.

### BRIEF DESCRIPTION OF THE SEVERAL VIEWS OF THE DRAWING

FIG. 1 is a cross-sectional view schematically showing a semiconductor device according to one embodiment of the invention.

FIG. 2 is a cross-sectional view schematically showing a step of a method of manufacturing a semiconductor device according to one embodiment of the invention.

FIG. 3 is a cross-sectional view schematically showing a step of the method of manufacturing a semiconductor device according to one embodiment of the invention.

FIG. 4 is a cross-sectional view schematically showing a step of the method of manufacturing a semiconductor device according to one embodiment of the invention.

FIG. 5 is a cross-sectional view schematically showing a step of the method of manufacturing a semiconductor device according to one embodiment of the invention.

FIG. 6 is a cross-sectional view schematically showing a step of the method of manufacturing a semiconductor device according to one embodiment of the invention.

FIG. 7 is a cross-sectional view schematically showing a step of the method of manufacturing a semiconductor device according to one embodiment of the invention.

FIG. 8 is a cross-sectional view schematically showing a modification of the semiconductor device according to one embodiment of the invention.

### DETAILED DESCRIPTION OF THE EMBODIMENT

The invention may provide a semiconductor device with improved reliability.

According to one embodiment of the invention, there is provided a semiconductor device comprising:

a semiconductor layer;

a transistor formed in the semiconductor layer;

a first interlayer dielectric formed above the semiconductor layer;

a plurality of first interconnect layers formed above the first interlayer dielectric;

a second interlayer dielectric formed over the first interlayer dielectric and the first interconnect layers;

a plurality of second interconnect layers and an electrode pad which are formed above the second interlayer dielectric, the second interconnect layers being uppermost interconnects;

a passivation layer formed over the second interlayer dielectric, the second interconnect layers, and the electrode pad; and

an opening formed in the passivation layer to expose at least part of the electrode pad,

a minimum distance between the second interconnect layers being greater than a minimum distance between the first interconnect layers.

In this semiconductor device, the minimum space between the second interconnect layers is greater than the minimum space between the first interconnect layers. If the minimum space between the second interconnect layers is smaller than the minimum space between the first interconnect layer, there may be a case where the thickness of the passivation layer must be increased to suppress formation of voids due to the passivation layer. In the semiconductor device according to this embodiment, since the minimum space between the second interconnect layers is greater than the minimum space between the first interconnect layers, formation of voids can be suppressed, whereby the thickness of the passivation layer can be reduced. As a result, the depth of the opening formed in the passivation layer can be reduced. If a bump is formed on the electrode pad in such a manner that the bump is embedded in the opening, a concave section is not formed in the surface of the bump over the opening. Even though a concave section is formed, the depth of the concave section can be reduced. Therefore, the semiconductor device according to this embodiment allows the bump and an interconnect substrate or the like to be connected successfully to ensure improved reliability.

The semiconductor device may further comprise:

a fuse formed in the same level as the first interconnect layers; and

another opening which is formed in the second interlayer dielectric and the passivation layer above the fuse, but does not expose the fuse.

In this semiconductor device, the minimum distance between the second interconnect layers may be greater than a thickness of the passivation layer.

According to one embodiment of the invention, there is provided a method of manufacturing a semiconductor device, the method comprising:

forming a transistor in a semiconductor layer;

forming a first interlayer dielectric above the semiconductor layer;

forming a plurality of first interconnect layers and a fuse above the first interlayer dielectric;

forming a second interlayer dielectric over the first interlayer dielectric, the first interconnect layers, and the fuse;

forming a plurality of second interconnect layers and an electrode pad above the second interlayer dielectric;

forming a passivation layer over the second interlayer dielectric, the second interconnect layers, and the electrode pad;

forming an opening in the passivation layer to expose at least part of the electrode pad; and

forming another opening in the second interlayer dielectric and the passivation layer above the fuse in such a manner that the fuse is not exposed,

a minimum distance between the second interconnect layers being greater than a minimum distance between the first interconnect layers.

These embodiments of the invention will be described below, with reference to the drawings.

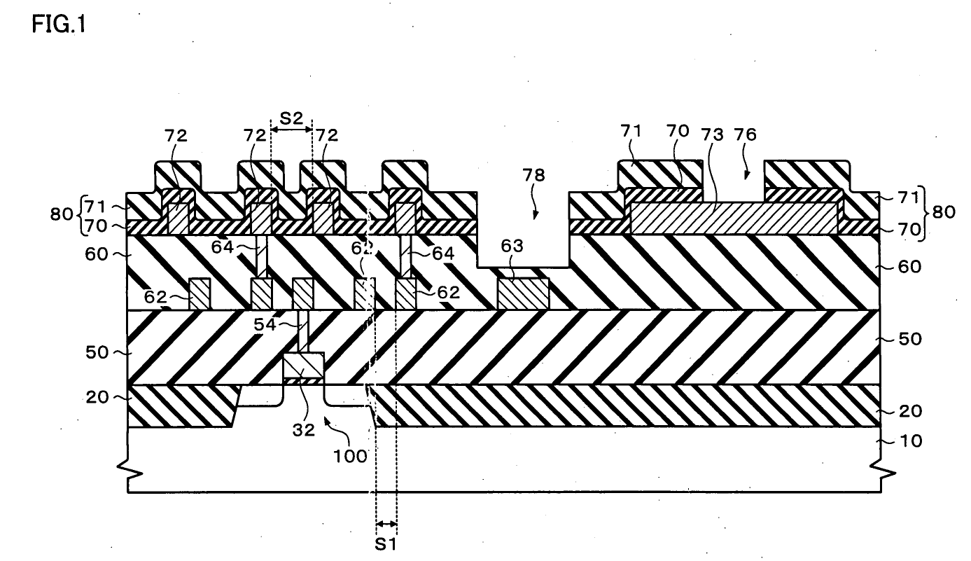

A semiconductor device according to one embodiment of the invention is described below. FIG. 1 is a cross-sectional view schematically showing the semiconductor device according to this embodiment.

As shown in FIG. 1, the semiconductor device according to this embodiment includes a semiconductor layer 10, a transistor 100, a first interlayer dielectric 50, a first interconnect layer 62, a second interlayer dielectric 60, a second interconnect layer 72, an electrode pad 73, a passivation layer 80, and an opening (hereinafter also referred to as “first opening”) 76.

The semiconductor layer 10 may be a silicon substrate or the like. The transistor 100 is formed on the semiconductor layer 10. The transistor 100 may be a MOS transistor, for example. An element isolation region 20 is formed in a region surrounding the transistor 100. The transistor 100 is isolated from other elements (not shown) by the element isolation region 20.

The first interlayer dielectric 50 is formed over the semiconductor layer 10. Specifically, the first interlayer dielectric 50 is formed on the transistor 100 and the element isolation region 20. The first interconnect layer 62 is formed on the first interlayer dielectric 50. In the example shown in FIG. 1, the first interconnect layer 62 is the first layer of the interconnect layers. The first interconnect layer 62 is not limited to the first layer of the interconnect layers, but may be an interconnect layer positioned in a layer higher than the first layer. The first interconnect layer 62 may be connected with a gate electrode 32 of the transistor 100 through a contact layer 54 provided in a contact hole formed through the first interlayer dielectric 50, for example.

The semiconductor device according to this embodiment may further include a fuse 63 formed in the same layer as the first interconnect layer 62. The fuse 63 is formed on the first interlayer dielectric 50.

The second interlayer dielectric 60 is formed on the first interlayer dielectric 50, the first interconnect layer 62, and the fuse 63. The second interconnect layer 72 is formed on the second interlayer dielectric 60. The second interconnect layer 72 is the uppermost interconnect layer. In the example shown in FIG. 1, the second interconnect layer 72 is the second layer of the interconnect layers. The minimum space S2 between the second interconnect layers (hereinafter also referred to as “second interconnect layer space”) is larger than the minimum space S1 between the first interconnect layers (hereinafter also referred to as “first interconnect layer space”). The space means the space of a so-called line and space (L/S), and is defined by the distance between two adjacent interconnect layers formed in the same layer. The minimum space means the shortest distance between the interconnect layers (distance between two adjacent interconnect layers formed in the same layer). The line and space (L/S) of the second interconnect layer 72 is 0.6/1.2 (micrometers), and the line and space (L/S) of the first interconnects 62 layer is 0.24/0.26 (micrometers), for example. In other words, the second interconnect layer space S2 is 1.2 micrometers, and the first interconnect layer space S1 is 0.26 micrometers, for example.

In the semiconductor device according to this embodiment, the second interconnect layer space S2 may be greater that the thickness of the passivation layer 80. This allows the passivation layer to readily adhere to the sidewall of the second interconnect layer 72. Specifically, the second interconnect layer space S2 is preferably 1.2 times the thickness of the passivation layer 80, for example. This value is calculated based on the amount ratio (coverage) of the passivation layer 80 adhering to the sidewall of the second interconnect layer 72. For example, when the thickness of the passivation layer 80 is 1 micrometer, the second interconnect layer space S2 is preferably 1.2 micrometers.

The second interconnect layer 72 may be connected with the first interconnect layer 62 through a contact layer 64 provided in a contact hole formed through the second interlayer dielectric 60, for example. The electrode pad 73 is formed on the second interlayer dielectric 60.

The passivation layer 80 is formed on the second interlayer dielectric 60, the second interconnect 72, and the electrode pad 73. The passivation layer 80 may have a two-layer structure formed of a silicon oxide layer 70 and a silicon nitride layer 71 formed thereon, for example. In the semiconductor device according to this embodiment, the total thickness of the passivation layer 80 may be 1 micrometer, the thickness of the silicon oxide layer 70 may be 0.4 micrometer, and the thickness of the silicon nitride layer 71 may be 0.6 micrometer, for example.

The first opening 76 which exposes at least a part of the electrode pad 73 is formed in the passivation layer 80. In the example shown in FIG. 1, the first opening 76 exposes only a part of the upper surface of the electrode pad 73. Another opening (hereinafter referred to as “second opening”) 78 which does not expose the fuse 63 may be formed in the passivation layer 80 and the second interlayer dielectric 60.

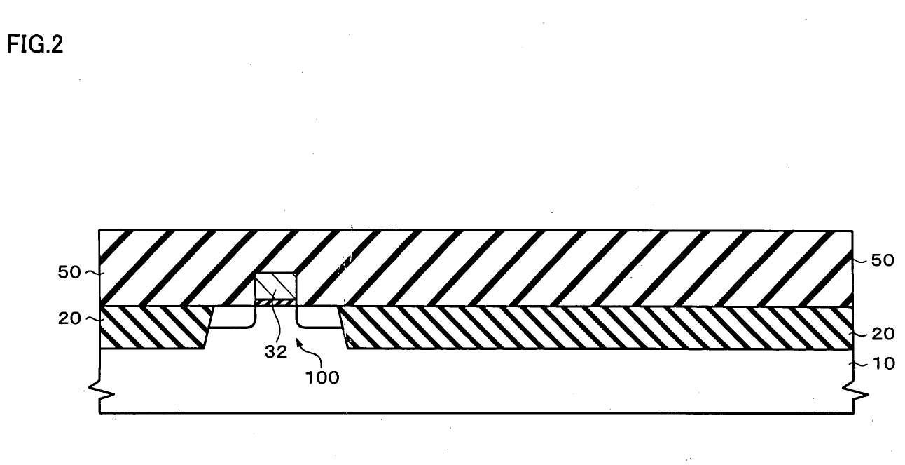

A method of manufacturing a semiconductor device according to one embodiment of the invention is described below. FIGS. 2 to 7 are cross-sectional views schematically showing steps of the method of manufacturing a semiconductor device according to this embodiment. FIGS. 2 to 7 correspond to the cross-sectional view shown in FIG. 1.

(1) As shown in FIG. 2, the element isolation region 20 is formed in a predetermined region of the semiconductor layer 10 using an STI method or the like. As shown in FIG. 2, the transistor 100 is formed on the surface of the semiconductor layer 10 and the nearby region by a known method. As shown in FIG. 2, the first interlayer dielectric 50 is formed over the entire surface of the semiconductor layer 10 by chemical vapor deposition (CVD) or the like.

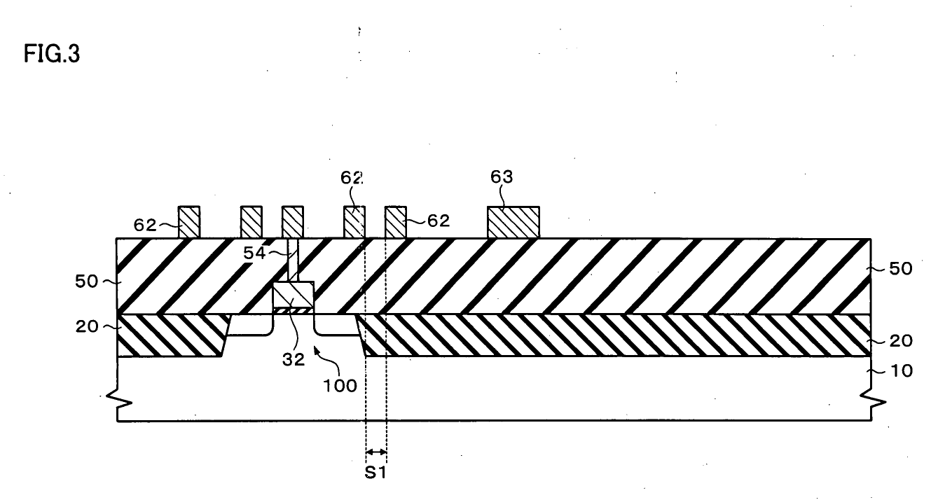

(2) An opening (contact hole) is formed in the first interlayer dielectric 50 by lithography and etching. As shown in FIG. 3, the contact layer 54 embedded in the contact hole is formed by a known method. Then, the first interconnect layer 62 and the fuse 63 are formed on the first interlayer dielectric 50. The first interconnect layer 62 is formed in such a manner that the minimum space S1 between the first interconnect layers becomes smaller than the second interconnect layer space S2 (see FIG. 1). The first interconnect layer 62 and the fuse 63 are provided by forming a conductive layer (not shown) over the entire surface of the first interlayer dielectric 50, and patterning the conductive layer.

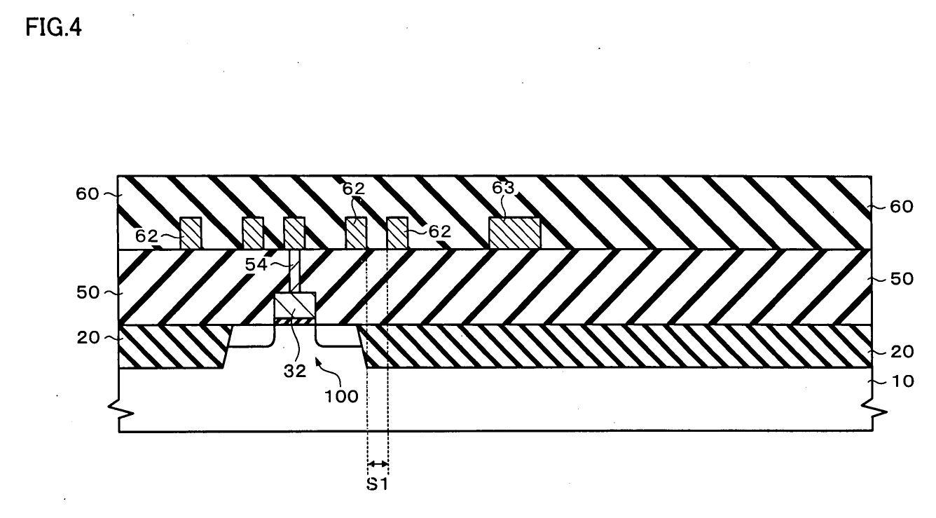

(3) As shown in FIG. 4, the second interlayer dielectric 60 is formed over the entire surface of the first interlayer dielectric 50, the first interconnect layer 62, and the fuse 63 by CVD or the like.

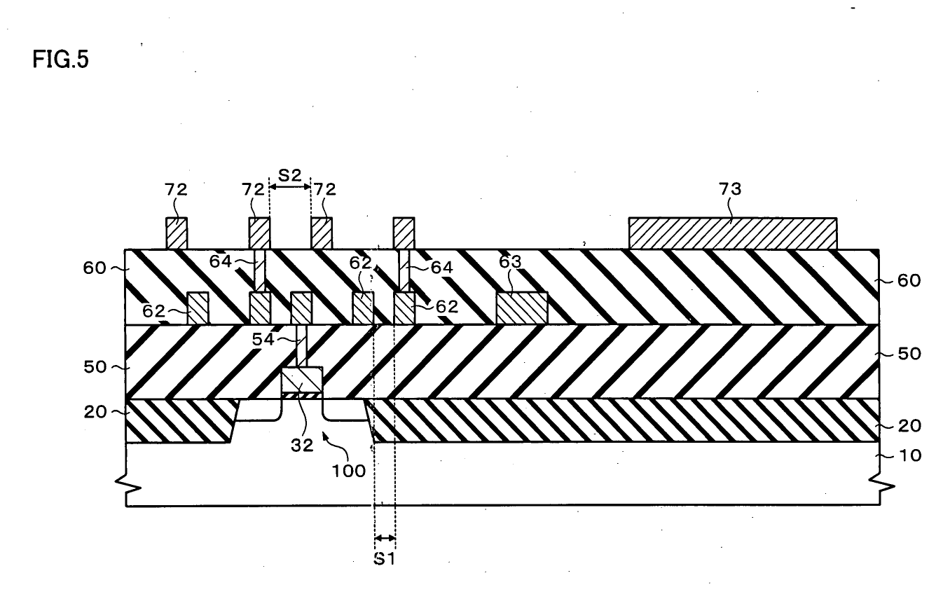

(4) An opening (via hole) is formed in the second interlayer dielectric 60 by lithography and etching. As shown in FIG. 5, the contact layer 64 embedded in the via hole is formed by a known method. Then, the second interconnect layer 72 and the electrode pad 73 are formed on the second interlayer dielectric 60. The second interconnect layer 72 is formed in such a manner that the minimum space S2 between the second interconnect layers becomes greater than the first interconnect layer space S1 (see FIG. 1). The second interconnect layer 72 and the electrode pad 73 are provided by forming a conductive layer (not shown) over the entire surface of the second interlayer dielectric 60, and patterning the conductive layer, for example.

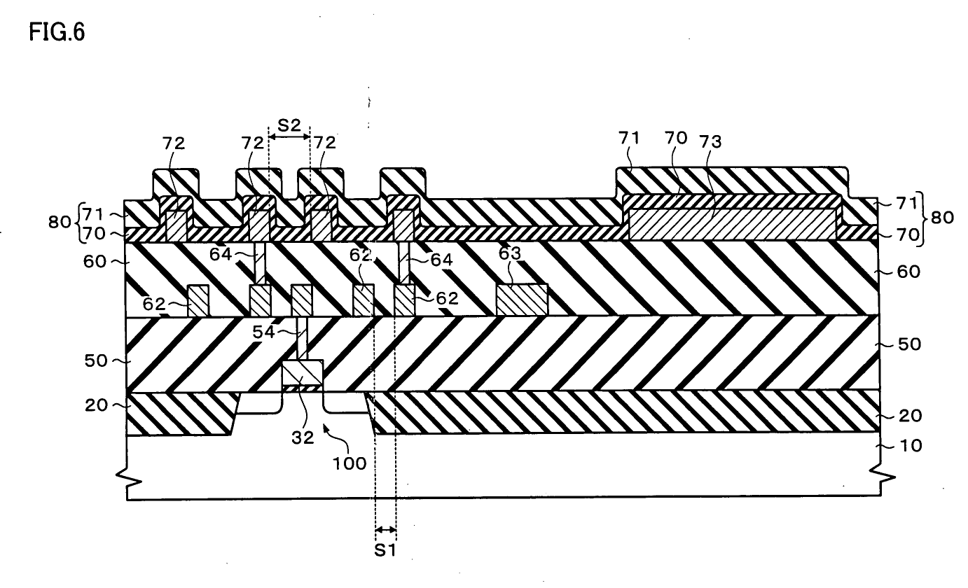

(5) As shown in FIG. 6, the silicon oxide layer 70 is formed over the entire surfaces of the second interlayer dielectric 60, the second interconnect layer 72, and the electrode pad 73. There are no specific restrictions on the method of forming the silicon oxide layer 70. It is preferable to use a method other than high-density plasma CVD. As the method of forming the silicon oxide layer 70, plasma CVD or the like is preferable.

As shown in FIG. 6, the silicon nitride layer 71 is formed over the entire surface of the silicon oxide layer 70. As the method of forming the silicon nitride layer 71, plasma CVD or the like is preferable.

The passivation layer 80 with a two-layer structure formed of the silicon oxide layer 70 and the silicon nitride layer 71 is thus formed, as shown in FIG. 6.

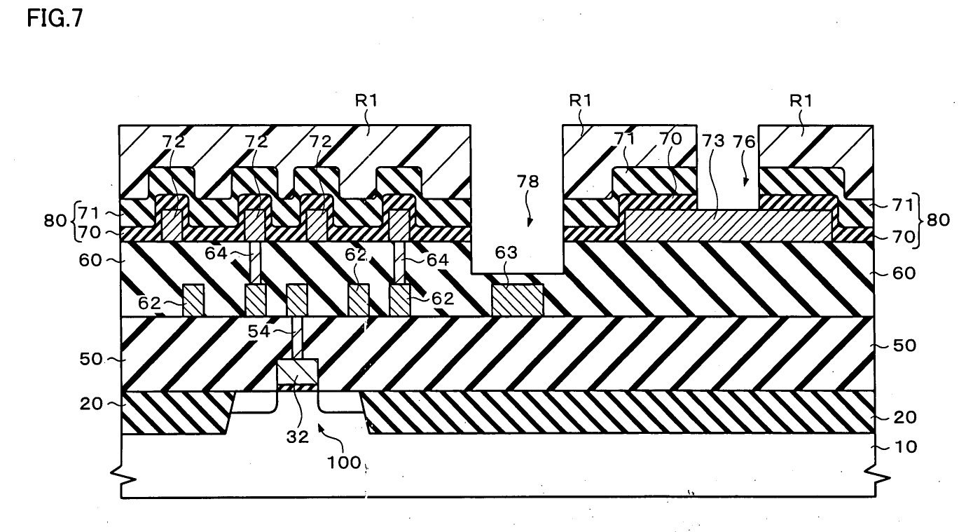

(6) As shown in FIG. 7, a resist layer R1 with a specific pattern is formed on the passivation layer 80 (on the silicon nitride layer 71 in the example shown in FIG. 7). Specifically, the resist layer R1 is formed in such a manner that it has openings in the region where the first opening 76 is formed and in the region where the second opening 78 is formed.

Subsequently, the passivation layer 80 is etched using the resist layer R1 as a mask so that an opening is formed in the passivation layer to expose at least a part of the electrode pad 73. Simultaneously, the passivation layer 80 and the second interlayer dielectric 60 are etched using the resist layer R1 as a mask so that an opening is formed in the second interlayer dielectric 60 and the passivation layer 80 in the region located over the fuse 63 in such a manner that the fuse 63 is not exposed. By the above step, the first opening 76 and the second opening 78 are formed. In the above step, etching is continued until the second opening 78 is formed, in other words, until a part of the second interlayer dielectric 60 located over the fuse 63 has a desired thickness. In this case, since the electrode pad 73 serves as an etching stopper layer, formation of the opening in the passivation layer 80 located on the electrode 73 stops at the upper surface of the electrode pad 73. The resist layer R1 is then removed.

The semiconductor device according to this embodiment may be manufactured by the above-described steps.

After the above-described steps, a bump or the like may be formed by known process technology.

In the semiconductor device according to this embodiment, the second interconnect layer space S2 is greater than the first interconnect layer space S1. If the second interconnect layer space S2 is smaller than the first interconnect layer space S1, the passivation layer 80 (in particular, the silicon oxide layer 70 in the first layer) is required to be thick to suppress formation of voids due to the passivation layer 80. In the semiconductor device according to this embodiment, since the second interconnect layer space S2 is greater than the first interconnect layer space S1, formation of voids can be suppressed, whereby the thickness of the passivation layer 80 (in particular, the thickness of the silicon oxide layer 70 in the first layer) can be reduced. This allows the depth of the first opening 76 formed in the passivation layer 80 to be reduced. In other words, the difference in height between the upper surface of the electrode pad 73 and the upper surface of the passivation layer 80 formed on the electrode pad 73 can be reduced. By this configuration, if a bump is formed on the electrode pad 73 in such a manner that the bump is embedded in the first opening 76, a concave section is not formed in the surface of the bump at a position over the first opening 76. Even if a concave section is formed, its depth can be small. The semiconductor device according to this embodiment allows the bump and an interconnect substrate (not shown) or the like to be connected successfully to improve reliability.

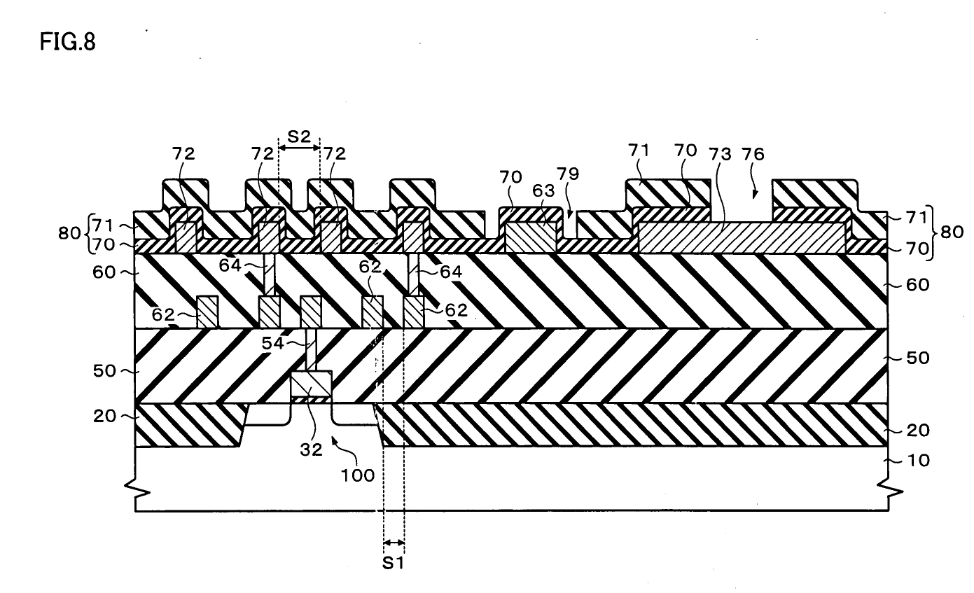

In the semiconductor device according to this embodiment, the fuse 63 is formed in the same layer as the first interconnect layer 62. When the fuse 63 and the second interconnect layer 72 are present in the same layer, the fuse 63 is covered with the silicon oxide layer 70 (see FIG. 8), for example. In this case, to protect the fuse 63, the silicon oxide layer 70 is required to have a certain thickness. In the semiconductor device according to this embodiment, since the fuse 63 is covered with the second interlayer dielectric 60, it is unnecessary to increase the thickness of the silicon oxide layer 70 to protect the fuse 63. In the semiconductor device according to this embodiment, in contrast to the case where the fuse 63 and the second interconnect layer 72 are formed in the same layer, the thickness of the silicon oxide layer 70 and the thickness of the passivation layer 80 can be reduced without restrictions. As a result, the depth of the first opening 76 formed in the passivation layer 80 can be reduced. Therefore, the semiconductor device according to this embodiment allows the bump (not shown) and an interconnect substrate (not shown) to be connected successfully to ensure reliability, as mentioned above.

In the method of manufacturing a semiconductor device according to this embodiment, an opening is formed in the passivation layer 80 to expose at least a part of the electrode pad 73, and an opening is formed in the second interlayer dielectric 60 and the passivation layer 80 in the region located over the fuse 63 in such a manner that the fuse 63 is not exposed (see FIG. 7). In this way, the second opening 78 is formed simultaneously with the first opening 76. This simplifies the manufacturing process in contrast to the case where the first opening 76 and the second opening 78 are formed in separate steps.

In the method of manufacturing a semiconductor device according to this embodiment, the first interconnect layer and the second interconnect layer are formed so that the second interconnect layer space S2 is greater than the first interconnect layer space S1. By this configuration, as compared with the case where the second interconnect layer space S2 is smaller than the first interconnect layer space S1, the second interconnect layer 72 can be readily embedded in the passivation layer 80 (the silicon oxide layer 70 and the silicon nitride layer 71). In addition, by making the second interconnect layer space S2 1.2 times the thickness of the passivation layer 80, the second interconnect layer 72 can be embedded successfully even if the silicon oxide layer 70 is formed by plasma CVD instead of high-density plasma CVD. Specifically, in the method for manufacturing a semiconductor device according to this embodiment, since high-density plasma CVD is not needed to form the silicon oxide layer 70 in order to reliably cover the second interconnect layer 72, production cost can be reduced. For example, when covering the second interconnect layer 72 by utilizing high-density plasma CVD, the silicon oxide layer 70 must be generally formed to have a thickness approximately equal to that of the second interconnect layer 72. This results in an increased thickness of the passivation layer 80. On the other hand, when plasma CVD is used to form the silicon oxide layer 70, the second interconnect layer 72 can be covered with the silicon oxide layer 70 formed to have a thickness smaller than that when using plasma CVD.

In the method of manufacturing a semiconductor device according to this embodiment, the first interconnect layer and the second interconnect layer are formed so that the second interconnect layer space S2 is greater than the first interconnect layer space S1. By this configuration, formation of voids due to the passivation layer 80 can be suppressed. Therefore, the thickness of the passivation layer 80 can be reduced, whereby the depth of the first opening 76 can be reduced. If the depth of the first opening 76 is reduced by a method described below, the number of manufacturing steps is increased as compared with the method of manufacturing a semiconductor device according to this embodiment.

Specifically, immediately after forming the silicon oxide layer 70, a resist layer which exposes only a part of the silicon oxide layer 70 located over the electrode pad 73 is formed. Then, the silicon oxide layer 70 located over the electrode pad 73 is etched using the resist layer as a mask to reduce the thickness of the silicon oxide layer 70. Subsequently, the silicon nitride layer 71 is formed to provide the first opening 76. By this method, the first opening 76 has a reduced depth as compared with the case where the part of the silicon oxide layer 70 located over the electrode pad 73 is not etched, as mentioned above.

In contrast to the case where the depth of the first opening 76 is reduced by the above-mentioned method, the method of manufacturing a semiconductor device according to this embodiment can reduce the number of manufacturing steps to simplify the manufacturing process.

A modification of the semiconductor device according to one embodiment of the invention is described below. The following modification is only an example. The invention is not limited to the following modification.

The above example illustrates the case where the fuse 63 is formed in the layer below the electrode pad 73. Note that the fuse 63 and the electrode pad 73 may be formed in the same layer, as shown in FIG. 8. In other words, the fuse 63 may be formed in the same layer as the uppermost interconnect layer (the second interconnect layer 72). FIG. 8 is a cross-sectional view schematically showing the semiconductor device in this case.

In the example shown in FIG. 8, the fuse 63 is covered with the silicon oxide layer 70. The silicon nitride layer 71 has an opening 79 (hereinafter referred to as “third opening”) formed at least over the fuse 63. In the example shown in FIG. 8, the third opening 79 is formed over and on the side of the fuse 63. When manufacturing the semiconductor device shown in FIG. 8, the first opening 76 and the third opening 79 may be formed in separate steps.

Although only some embodiments of the invention have been described in detail above, those skilled in the art will readily appreciate that many modifications are possible in the embodiments without materially departing from the novel teachings and advantages of this invention. Accordingly, all such modifications are intended to be included within the scope of the invention.

What is claimed is:

1. A semiconductor device comprising:
a semiconductor layer;
a transistor formed in the semiconductor layer;
a first interlayer dielectric formed above the semiconductor layer;
a plurality of first interconnect layers formed above the first interlayer dielectric;
a second interlayer dielectric formed over the first interlayer dielectric and the first interconnect layers;
a plurality of second interconnect layers and an electrode pad which are formed above the second interlayer dielectric, the second interconnect layers being uppermost interconnects;
a passivation layer formed over the second interlayer dielectric, the second interconnect layers, and the electrode pad; and
an opening formed in the passivation layer to expose at least part of the electrode pad,
a minimum distance between the second interconnect layers being greater than a minimum distance between the first interconnect layers.

2. The semiconductor device as defined in claim 1, further comprising:
a fuse formed in the same level as the first interconnect layers; and
another opening which is formed in the second interlayer dielectric and the passivation layer above the fuse, but does not expose the fuse.

3. The semiconductor device as defined in claim 1,
wherein the minimum distance between the second interconnect layers is greater than a thickness of the passivation layer.

4. The semiconductor device as defined in claim 1, further comprising:
a fuse formed in the same level as the first interconnect layers; and
another opening which is formed in the second interlayer dielectric and the passivation layer above the fuse, but does not expose the fuse,
wherein the minimum distance between the second interconnect layers is greater than a thickness of the passivation layer.

5. A method of manufacturing a semiconductor device, the method comprising:
forming a transistor in a semiconductor layer;
forming a first interlayer dielectric above the semiconductor layer;
forming a plurality of first interconnect layers and a fuse above the first interlayer dielectric;
forming a second interlayer dielectric over the first interlayer dielectric, the first interconnect layers, and the fuse;
forming a plurality of second interconnect layers and an electrode pad above the second interlayer dielectric;
forming a passivation layer over the second interlayer dielectric, the second interconnect layers, and the electrode pad;
forming an opening in the passivation layer to expose at least part of the electrode pad; and
forming another opening in the second interlayer dielectric and the passivation layer above the fuse in such a manner that the fuse is not exposed,
a minimum distance between the second interconnect layers being greater than a minimum distance between the first interconnect layers.
